(19) United States
(12) Patent Application Publication
(10) Pub. No.: US 2007/0102834 A1
(43) Pub. Date: May 10, 2007

(54) Strain-compensated metastable compound base heterojunction bipolar transistor

(76) Inventors: Darwin G. Enicks, Colorado Springs, CO (US); John T. Chaffee, Colorado Springs, CO (US); Darnian A. Carver, Colorado Springs, CO (US)

Correspondence Address: SCHNECK & SCHNECK, P.O. BOX 2-E, SAN JOSE, CA, 95109-0005, US

(21) Appl. No.: 11/268,154

(22) Filed: Nov. 7, 2005

(51) Int. Cl. H01L 21/20

(52) U.S. Cl. 257/E29.193; 438/483

(57) ABSTRACT

A method for pseudomorphic growth and integration of an in-situ doped, strain-compensated metastable compound base into an electronic device, such as, for example, a SiGe NPN HBT, by substitutional placement of strain-compensating atomic species. The invention also applies to strained layers in other electronic devices such as strained SiGe, Si in MOS applications, vertical thin film transistors (VTFT), and a variety of other electronic device types. Devices formed from compound semiconductors other than SiGe, such as, for example, GaAs, InP, and AlGaAs are also amenable to beneficial processes described herein.

### TECHNICAL FIELD

The invention generally relates to methods of fabrication of integrated circuits (ICs). More specifically, the invention is a method of fabricating and integrating a metastable silicon-germanium (SiGe) base region into a heterojunction bipolar transistor (HBT).

### BACKGROUND ART

The SiGe HBT has significant advantages over a silicon (silicon) bipolar junction transistor (BJT) in gain, frequency response, noise parameters, and retains an ability to integrate with CMOS devices at relatively low cost. Cutoff frequencies (Fₜ) of SiGe HBT devices have been reported to exceed 300 GHz, which is favorable as compared to GaAs devices. However, GaAs devices are relatively high in cost and cannot achieve the level of integration, such as, for example, of BiCMOS devices. The silicon compatible SiGe HBT provides a low cost, high speed, low power solution that is quickly replacing other compound semiconductor devices.

Advantages of SiGe are realized by a bandgap reduction creating an energy band offset at the Si—SiGe heterojunction(s) of the HBT, thereby resulting in increased current densities for a given base-emitter bias and higher gains. Also, a lower resistivity is possible with addition of Ge to a Si lattice. The higher current densities and lower base resistance values allow improved unity gain cutoff frequencies and maximum oscillation frequencies than comparable silicon BJTs, and are comparable to other compound devices such as GaAs. However, the emitter collector breakdown voltage (especially BVCE0) is inversely proportional to the current gain (β). The structural and process changes required to enhance Fₜ and reduce power lead to higher and higher current gains and hence lower and lower collector-emitter breakdown voltages.

Elevated Ge fractions result in an increase in base recombination current and a reduction in current gain for a given layer thickness and doping level. This effect has been confirmed experimentally to extend beyond 30% Ge. References on defect formation in pseudomorphic SiGe with high Ge content suggests the effect will continue to increase for Ge fractions well above 40% (i.e., Kasper et al., “Properties of Silicon Germanium and SiGe:Carbon,” INSPEC, 2000). Therefore, a compromise of increasing the Ge fraction high enough to reduce current gain in high-speed devices provides a way to compensate for an inevitable increase in gain and degradation of BVCEO as basewidths continue to shrink.

However, there is a limit to how much Ge can be added to the Si lattice before excess strain relaxation and gross crystalline defects occur. A critical thickness (h_{c}) of a SiGe layer that is lattice matched to the underlying silicon is a function of (1) percentage of Ge; (2) SiGe film thickness; (3) cap layer thickness; (4) temperature of HBT filmstack processing; and (5) temperature of thermal anneals following a silicon-germanium deposition. Above the critical thickness, h_{c}, the SiGe film is in a metastable and/or unstable region, which implies it will relax readily with a large enough application of thermal energy. Therefore, the degree of metastability is largely a function of percent Ge, SiGe layer thickness, cap layer thickness, and process induced strain due to thermal energy. Construction of a SiGe base of a conventional SiGe HBT described to date is that of a stable, pseudomorphic, or lattice-matched layer. Contemporaneous state-of-the-art procedures include growing stable, strained or lattice-matched alloys of SiGe with carbon to prevent spreading of the boron profile in the base region.

Metastable film growth is typically avoided due to the fact that relaxation results in lattice imperfections. These imperfections result in recombination centers; hence, a reduction in minority carrier lifetime (τ_{b}) and an increase in base recombination current (I_{RB}) occurs. If not controlled, a resultant poor crystal quality due to lattice imperfections will degrade device performance. “Bridging” defects will also lead to excessive leakage current along with extremely low current gain. The film will also be very sensitive to process induced thermal stresses and therefore will not be manufacturable. Therefore, to avoid this type of degradation, the HBT designs to date result in a device with a base region that is in the stable region of film growth, which equates to a SiGe thickness that is equal to or below the critical thickness, h_{c}.

Properties of metastable SiGe are discussed in several papers such as D. C. Houghton, “Strain Relaxation Kinetics in Si₁₋ₓGeₓ/Si Heterostructures,” Journal of Applied Physics, Vol. 70, pp. 2136-2151 (Aug. 15, 1991), and G. S. Kar et al. “Effect of carbon on lattice strain and hole mobility in Si₁₋ₓGeₓ alloys,” Dept. of Physics and Meteorology, Indian Institute of Technology, Kharagpur 721302, India, Journal of Materials Science: Materials in Electronics, Vol. 13, pp. 49-55 (2002). Further, U.S. Pat. Nos. 6,586,297 (“the '297 patent”) and 6,781,214 (“the '214 patent”), to U'Ren et al. describe a “Metastable Base in a High-Performance HBT” and a “Method for Integrating a Metastable Base into a High Performance HBT and Related Structure,” respectively.

The '297 patent describes a heterojunction bipolar transistor that includes a metastable epitaxial silicon-germanium base on a single crystal collector and an emitter situated over a metastable epitaxial SiGe base.

The metastable epitaxial SiGe base is grown in an epitaxial reactor where the metastable epitaxial SiGe base is a strained crystalline structure including a conductivity altering dopant incorporated in-situ during film growth; the dopant is added for the sole purpose of establishing a specific conductivity type. The '297 patent describes a method that includes a short thermal anneal at temperatures of 900° C. to 950° C. to avoid relaxing the metastable SiGe film layer.

The '214 patent describes a heterojunction bipolar transistor fabricated by forming a metastable epitaxial SiGe base on a collector with a concentration of germanium greater than 20 atomic percent. An emitter is then fabricated over the metastable epitaxial SiGe base. The emitter is doped with an n- or p-type impurity depending on the transistor type, npn or pnp. The HBT is then heated in a spike anneal process to maintain the metastable epitaxial silicon-germanium base as a strained crystalline structure and to diffuse the dopants to form the emitter-base junction. The metastable epitaxial SiGe base is grown in an epitaxial reactor where the metastable epitaxial SiGe base is strained crystalline structure including a dopant incorporated in-situ during film growth; the dopant is added for the sole purpose of establishing a specific conductivity type. The '214 patent describes a method that includes a short thermal anneal at temperatures of 900° C. to 950° C. to avoid relaxing the metastable SiGe film layer.

However, the methods described in these aforementioned references for forming a metastable SiGe film are still very susceptible to adverse effects of thermal stress such as slip dislocations and threading dislocations; all of which are associated with film relaxation. In highly metastable films, relaxation can take place during extremely short time intervals during an anneal process, depending on the degree of metastability, such as the first fraction of a second during a short anneal and/or a flash anneal process.

Therefore, what is needed is a method to grow and integrate strain-compensated metastable SiGe layers for application to a SiGe HBT. Such a method should allow a skilled artisan to, for example, control and utilize defect density for device optimization, achieve extremely high energy band offsets and grades (ΔE_{G}(0) & ΔE_{G}(grade)) without incurring excess “bridging” defects, such as slip or threading dislocations, and provide a method to achieve high volume manufacturability of films that would normally be unreliable and/or unrepeatable due to their extremely metastable or even unstable properties.

Each of these improvements allows the use of films that would otherwise be highly metastable (or even unstable) films in order to realize the advantages offered with high concentrations of Ge.

### SUMMARY

The present invention is a method for pseudomorphic growth and integration of a strain-compensated metastable and/or unstable compound base, which may also be in-situ doped, into an electronic device, such as, for example, a SiGe NPN HBT, by substitutional and/or interstitial placement of strain-compensating atomic species. The method allows for control of defect density, and thus resultant control of minority carrier lifetime, base recombination current, base current and current gain, and breakdown. Additionally, the ability to achieve greater Ge fractions than is possible without strain compensation and maintain a strained, lattice matched film enables devices with greater energy band offsets and hence greatly improved current densities and hence significantly improved Fₜ and Fₘₐₓ figures.

The invention also applies to strained layers in a variety of other electronic device types including strained SiGe, strained Ge, and/or strained Si in MOS applications, vertical thin film transistors (VTFT), resonant tunnel diodes (RTD), and a variety of other electronic device types. Heterojunction and heterostructure devices formed from compound semiconductors other than SiGe, such as, for example, GaAs, InP, and AlGaAs may also be amenable to beneficial processes described herein. Any strain-compensating element that will incorporate substitutionally and/or interstitially are amendable to the methods presented herein.

Elements that do not significantly affect the conductivity are often times desirable. Therefore, when using strain compensating group IV semiconductors such as Si, Ge, and/or SiGe it might be desirable to avoid group II/III or group V/VI elements to avoid affecting the conductivity. However, this does not preclude the use of “conductivity altering” elements for the dual purpose of strain compensation and also to effectively alter the conductivity simultaneously.

An electronic device fabricated by the method described herein, in an exemplary embodiment, includes a substrate with a compound semiconductor film disposed over a first surface of the substrate. The compound semiconductor film is deposited in a metastable state by exceeding the critical thickness, h_{c}, for the germanium concentration being used and the thermal cycles employed in the process after the compound semiconductor film has been formed. A substitutional strain-compensating atomic species (e.g., carbon) is added in-situ during the film growth to control defect density and avoid complete relaxation during the remainder of processing.

### BRIEF DESCRIPTION OF THE DRAWINGS

FIG. 1 is an exemplary cross-section of a film stack used in forming a portion of an HBT in accordance with the present invention.

FIG. 2 is a curve depicting critical thickness as a function of Ge content.

FIG. 3 is an Xrd rocking curve of a strained, lattice-matched metastable SiGe film.

FIG. 4 is the Xrd rocking curve of FIG. 3 after a thermal anneal.

### DETAILED DESCRIPTION

A strain-compensating atomic species is a species that, when added, alters the lattice parameter of a crystalline film from its intrinsic value. The intrinsic lattice parameter is the lattice parameter of the film or layer without the strain compensating species. For strain compensation of SiGe, one strain-compensating atomic species is carbon. One atomic percent of substitutional carbon will compensate eight percent to ten percent of Ge. Additionally, carbon can be substitutionally placed to approximately 2.5 percent in SiGe, or enough carbon to strain compensate 20 to 25 percent of Ge. Therefore, pseudomorphic strain-compensated metastable and/or unstable films with Ge levels of greater than 40 percent are possible (i.e., using four percent to five percent carbon) for electronic device use.

Even though one exemplary embodiment provides for strain reduction, a strain compensating atomic species with a larger lattice constant than either Si or Ge could be added to purposely increase strain. This type of strain modification would be suitable as well, for instance as a tool for bandgap and/or lattice engineering; defect engineering could make good use of strain modification as well. Strain modification would also be useful for enhancing carrier mobility in a “strain-compensated film” and any adjacent film layers.

The method described herein differs from previous methods for formation of a SiGe HBT due to an emphasis on intentional growth of a metastable and/or unstable base layer and a calculated incorporation of substitutional and/or interstitial carbon. The substitutional and/or interstitial carbon strain compensates an HBT base region to avoid strain relaxation, and allows defectivity engineering to decouple current gain from IC and Fₜ enhancement, along with integrating downstream thermal anneal processes thus avoiding excess carbon diffusion and maintaining the film in a strained state.

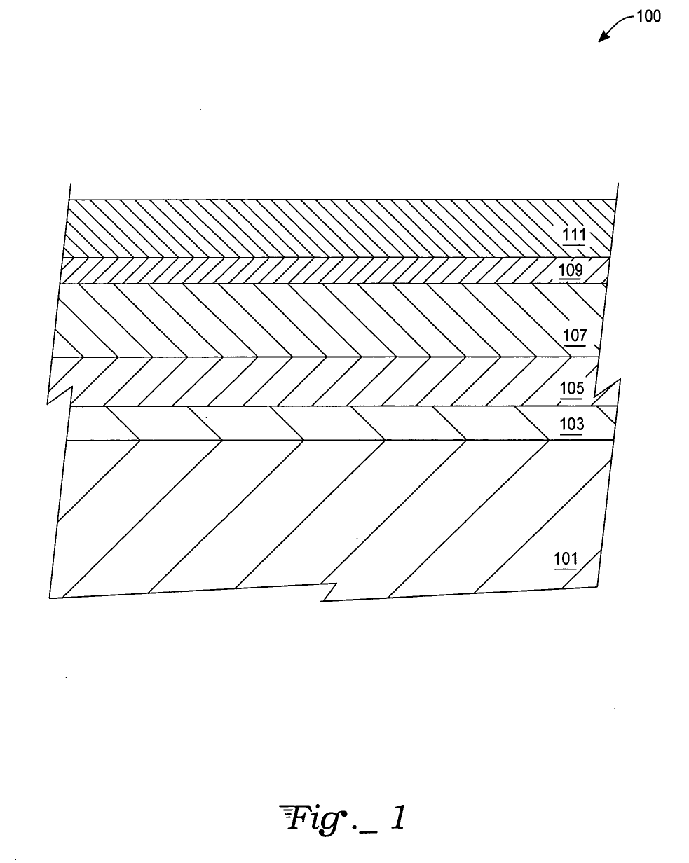

With reference to FIG. 1, an exemplary film stack 100 used in forming a strain-compensated metastable layer of an HBT includes a substrate 101, an epitaxial layer 103, an elemental seed layer 105, a strain-compensated metastable SiGe base region 107, an elemental cap layer 109, and a polysilicon emitter layer 111. One skilled in the art will recognize that other materials may be employed for the emitter layer 111 such as, for example, polySiGe.

In a specific exemplary embodiment, the substrate 101 is a p-type, 20 Ω-cm <100> silicon wafer. The epitaxial layer 103 is grown by LPCVD and can be either p-type or n-type depending on the technology application and the requirements for breakdown voltages and collector resistance. Arsenic and/or phosphorous may be doped into the epitaxial layer 103 and the substrate 101 to provide a low resistance collector region. The arsenic and phosphorous may be diffused or implanted. If implanted, one skilled in the art will recognize that the energy and dose of the implant must be determined by specific technology requirements for collector resistance, breakdown voltages, etc. A skilled artisan will also recognize that other methods may be employed to dope this region, such as diffusion or LPCVD (in-situ doping).

In the case of a silicon substrate 101, prior to growth, the silicon growth surface should be cleaned (typically with a wet chemistry such as hydrofluoric acid) to remove any native oxidation and surface contaminants. The elemental seedlayer 105, the metastable base region 107, and the elemental cap layer 109 may be fabricated during the same LPCVD process. Temperatures in the range of 500° C. to 900° C. are typically employed for epitaxial growth of each layer. Silane (SiH₄) and germane (GeH₄) are typical gases for silicon and SiGe deposition. Diborane (B₂H₆) and arsine (AsH₃) are common p- and n-type dopant sources. Hydrogen (H₂) may be utilized as a carrier gas, however other gases such as helium may be used.

In another specific exemplary embodiment, the substrate 101 is a <100> p-type silicon wafer, boron doped to a concentration of approximately 10¹⁵ atoms/cm³. Alternatively, the substrate 101 could also be, for example, an n-type silicon wafer or a substrate comprised of a compound semiconducting material such as silicon-germanium of either p-type or n-type conductivity. The substrate 101 may also be silicon-on-insulator (SOI) or silicon germanium-on-insulator. The epitaxial layer 103 is deposited to a thickness of between 0.3 μm and 2 μm, followed by the elemental seed layer 105. The epi layer is typically added as a low doped region to tailor breakdown voltages and/or collector resistance.

In this embodiment, the elemental seed layer 105 is comprised of silicon, which is epitaxially grown to a thickness range of 10 nm to 100 nm, although other semiconducting materials may be employed, such as silicon germanium with very low Ge content. The strain-compensated metastable SiGe layer 107 is deposited to a thickness greater than the critical thickness, h_{c}, followed by the elemental cap layer 109 comprised of, for example, silicon.

The critical thickness, h_{c}, is determined based on atomic percentage of Ge within an upper and lower bound of a metastable region. This critical thickness determination is based on historical work of People/Bean and Matthews/Blakeslee, and is known in to one of skill in art.

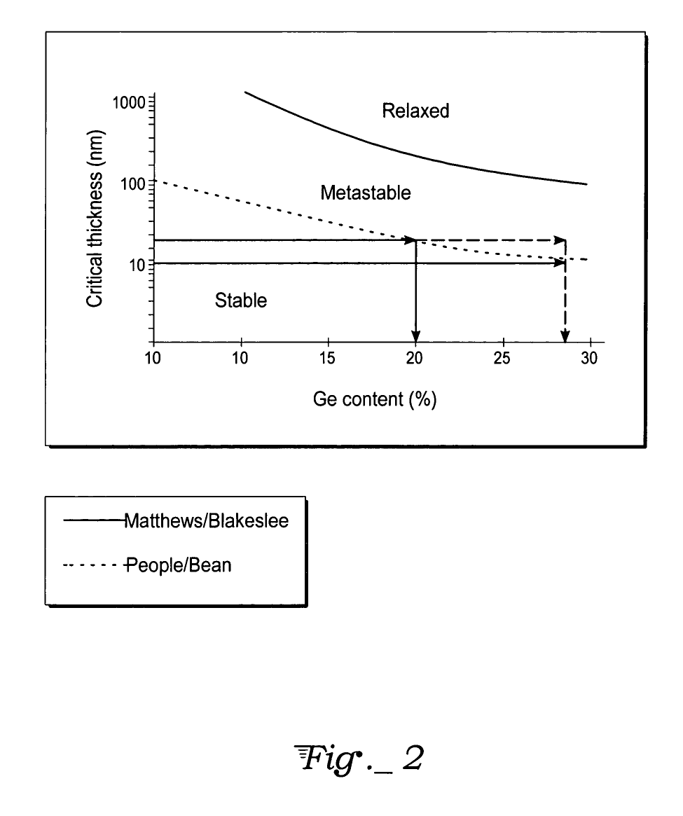

As an example, FIG. 2 shows that for a film with 20% Ge, the critical thickness, h_{c}, according to the People/Bean curve as defined by the bottom edge of the metastable region is approximately 20 nm, while a film with 28% Ge has an h_{c} of only 9 nm. Therefore, to grow a fully “strain compensated” film with 28% Ge that is also 20 nm thick, carbon may be added to reduce the lattice parameter and strain compensate 8% of Ge. The addition of 1% of carbon throughout the SiGe lattice of a 20 nm, 28% Ge film will reduce the strain to a level that approximates that of a 20 nm, 20% Ge film. However, one skilled in the art will recognize that it might be technologically desirable to provide only enough carbon to partially strain compensate, for example, adding 0.5% carbon for purposes of defect engineering. Alternatively, 2% carbon may be added for purposes of adding thermal processing robustness.

Additionally, one may desire to grow a film that resides well into the metastable region, and then to only partially compensate the film so-as to maintain a certain degree of metastability for defect and/or lattice engineering.

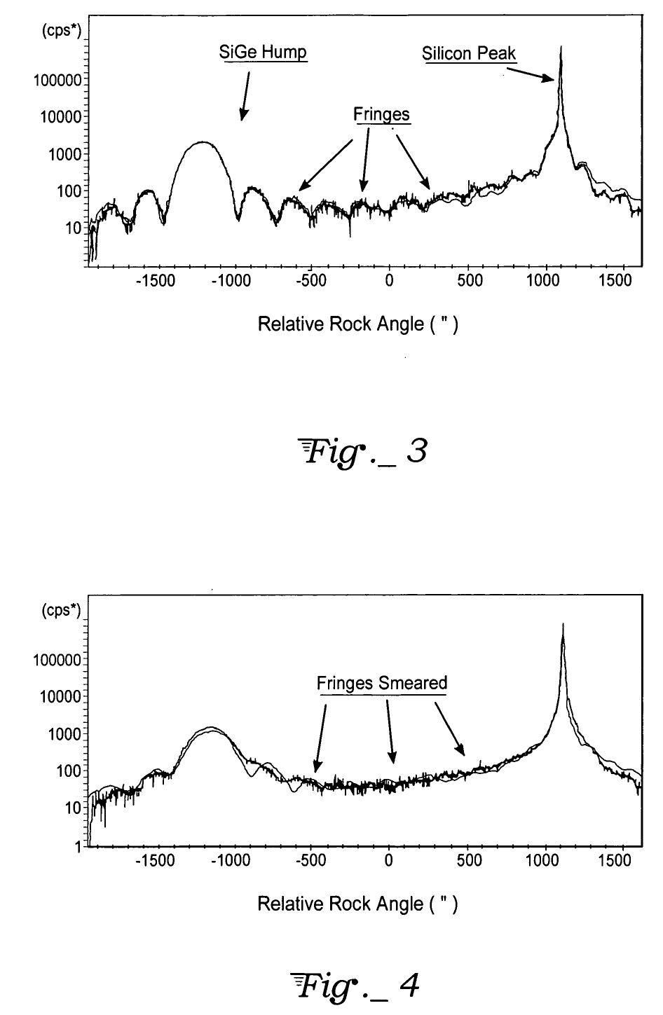

One skilled in the art will recognize that data and charts such as those of FIG. 2 are meant to provide approximations, but that other means, such as Xrd rocking curves are necessary to assist in determining where an optimum degree of metastability resides for a certain film structure and/or device. With reference to FIG. 3, one skilled in the art will know that distinct “fringe rings” between the silicon peak and the “SiGe hump” are indicative of lattice matched or strained layer.

The absence of and/or “smearing” of fringes in the Xrd rocking curves will indicate a film relaxation (FIG. 4) following a thermal anneal cycle. One skilled in the art will also know that Xrd rocking curves assessed following film growth and also following the downstream thermal treatments will provide information necessary for tailoring of the strain compensation process and/or thermal processes to avoid complete strain or lattice relaxation.

Other experimental approaches may be utilized, such as putting electrical devices through electrical testing to identify the acceptable level of strain compensation for a particular device or technology. This acceptable level will be determined by device electrical parameters, especially the collector current, base current, current gain, and breakdown voltages for an HBT. Other electrical parameters may be characterized and controlled for other device types and/or technologies.

Individual processes should be characterized with experimental methods to determine where their process resides with respect to the stable/metastable/relaxed regions as depicted by theoretical and empirically derived charts such as those discussed supra. This characterization will require analysis by such means of Xrd rocking curves, device electrical tests, and SIMS (secondary ion mass spectrometry) to reveal dopant diffusion, especially of strain compensating species such as carbon.

Even without the charts, the Xrd rocking curves can provide the quantitative and qualitative data necessary for developing strain compensated films, and that the “rule of thumb” for 1% carbon to compensate 8% to 10% Ge is a generally accepted guideline. Some metastable and/or unstable films and/or devices might require more or less carbon, depending on such factors as the film geometry, thermal stresses, and physically induced stresses (from adjacent films and structures) not accounted for in contemporary theoretical and empirical bodies of knowledge. Therefore, the guidelines provided herein will facilitate a development of metastable “strain compensated” films and/or devices and are intended as a system for providing an improved process and device. The guidelines also provide greater degrees of design engineering flexibility for bandgap engineering (i.e. J_{c}, Fₜ, Fₘₐₓ) and defectivity and/or lattice engineering (i.e., minority carrier lifetime engineering, base recombination current engineering, base current engineering, current gain engineering, and breakdown optimization).

With further reference to FIG. 1, the polysilicon emitter layer 111, in this exemplary embodiment, is comprised of n-type polysilicon that may be deposited to a thickness between 0.05 μm and 0.30 μm. However, other films such as polySiGe may also be employed.

A carbon precursor (for example, methane (CH₄) or acetylene (C₂H₂) ) is utilized during growth of the strain-compensated metastable SiGe layer 107 to add carbon. Precursors for formation of the strain-compensated metastable SiGe layer 107 include, for example, methyl silane (CH₃SiH₃), silane (SiH₄), and germane (GeH₄) for the carbon, silicon, and germanium components respectively. Hydrogen (H₂) is typically employed as a carrier gas for all layer depositions. In-situ doping with a conductivity altering dopant of a thin section near the center of the strain-compensated metastable SiGe layer 107 creates a p-type neutral base region. This neutral base region is sandwiched between two SiGe setback or spacer layers (not shown). The p-type impurity may be boron, commonly supplied with a diborane (B₂H₆) precursor. The elemental cap layer 109 is epitaxially grown on top of the strain-compensated metastable SiGe layer 107. The elemental cap layer 109 (silicon) maintains the SiGe layer in a strained state. Cap layers are typically grown with a thickness between 0.05 μm and 0.1 μm. A skilled artisan will recognize that the cap layer maintains strain equilibrium within the SiGe layer, and that the thickness is tailored as appropriate.

A profile of the Ge associated with the strain-compensated metastable SiGe layer 107 is generally that of a trapezoid, although a skilled artisan will recognize that other Ge profiles, such as triangular, box, or profiles with curvature are possible. The polysilicon emitter layer 111 may be, for example, n-type in-situ doped polysilicon. Arsine (ASH₃) may be used as an n-type dopant precursor employing hydrogen as a carrier gas for the process. The emitter layer 111 may be monocrystalline, polycrystalline, amorphous, or a compound material of a mono, poly, or amorphous construction. In a specific exemplary embodiment, a SiGe deposition temperature is in the range of 550° C. to 650° C., although temperatures less than 600° C. may be preferred for many advanced fabrication processes in general, with a processing pressure range of 1 torr to 100 torr. Pseudomorphic SiGe growth is possible at higher temperatures, such as up to or even exceeding 900° C.

Although the present invention is described in terms of exemplary embodiments, a skilled artisan will realize that techniques described herein can readily be adapted to other forms of fabrication techniques and devices. For example, the strain-compensation techniques could be applied to other technologies such as FinFET, surround gate FET, vertical thin film transistors (VTFT), hyper-abrupt junctions, resonant tunnel diodes (RTD), and optical waveguides for photonics. Therefore, profiles, thicknesses, and concentrations of the strain-compensated metastable SiGe layer 107 can be selected to accommodate a variety of needs. The metastable SiGe layer 107 could also be strain compensated with other elements, which may induce a diminished diffusivity for a given dopant type.

Also, although process steps and techniques are described in detail, a skilled artisan will recognize that other techniques and methods may be utilized, which are still included within a scope of the appended claims. For example, there are several techniques used for depositing and doping a film layer (e.g., chemical vapor deposition, plasma-enhanced chemical vapor deposition, molecular beam epitaxy, atomic layer deposition, etc.). Although not all techniques are amenable to all film types described herein, one skilled in the art will recognize that multiple and alternative methods may be utilized for depositing or otherwise forming a given layer and/or film type.

Additionally, many industries allied with the semiconductor industry could make use of the strain-compensation technique. For example, a thin-film head (TFH) process in the data storage industry, an active matrix liquid crystal display (AMLCD) in the flat panel display industry, or the micro-electromechanical industry (MEM) could readily make use of the processes and techniques described herein. The term “semiconductor” should thus be recognized as including the aforementioned and related industries. The drawing and specification are, accordingly, to be regarded in an illustrative rather than a restrictive sense.

What is claimed is:

1. A method for fabricating a compound semiconductor film, the method comprising:
providing a substrate, the substrate having a first surface;
forming the compound semiconductor film over the first surface of the substrate, the compound semiconductor film having a high concentration of a first semiconducting material of the compound semiconductor such that the compound semiconductor is in a metastable state; and
doping the compound semiconductor film with a strain-compensating atomic species.

2. The method of claim 1, further comprising selecting a concentration of the strain-compensating species to control a defect density and enhance bandgap or lattice characteristics.

3. The method of claim 1 wherein the compound semiconductor is comprised substantially of silicon germanium.

4. The method of claim 3 wherein the first semiconducting material of the compound semiconductor is germanium.

5. The method of claim 1 wherein the compound semiconductor is comprised substantially of indium gallium phosphide.

6. The method of claim 1 wherein the compound semiconductor is comprised substantially of silicon carbide.

7. The method of claim 1 wherein the compound semiconductor is comprised substantially of gallium arsenide.

8. The method of claim 1 wherein the compound semiconductor is comprised substantially of indium phosphide.

9. The method of claim 1 wherein the compound semiconductor is comprised substantially of aluminum gallium arsenide.

10. The method of claim 1 wherein the strain-compensating species is carbon.

11. The method of claim 1 wherein the strain-compensating species is selected to reduce a lattice strain of the compound semiconductor.

12. The method of claim 1 wherein the strain-compensating species is selected to increase a lattice strain of the compound semiconductor.

13. The method of claim 1 wherein the step of doping the compound semiconductor film with the strain-compensating atomic species is performed in-situ.

14. The method of claim 1, wherein the strain-compensating atomic species is selected to alter carrier recombination.

15. The method of claim 1, wherein the strain-compensating atomic species is selected so as to alter a conduction band structure.

16. The method of claim 1, wherein the strain-compensating atomic species is selected so as to alter a valence band structure.

17. The method of claim 1 further comprising profiling the first semiconducting material to have a trapezoidal shape.

18. The method of claim 1 further comprising profiling the first semiconducting material to have a triangular shape.

19. The method of claim 1 further comprising profiling the first semiconducting material to have a box shape.

20. The method of claim 1 further comprising profiling the first semiconducting material to have a curved shape.

21. The method of claim 1 wherein the step of formation of the compound semiconductor occurs at a temperature in a range of 500° C. to 900° C.

22. The method of claim 1 wherein the step of formation of the compound semiconductor occurs at a temperature in a range of 500° C. to less than 600° C.

23. The method of claim 1 further comprising forming the compound semiconductor film to a thickness greater than a critical thickness, h_{c}.

24. An electronic device comprising:
a substrate;
a compound semiconductor film disposed over a first surface of the substrate, the compound semiconductor film having a high concentration of a first semiconducting material of the compound semiconductor such that the first semiconducting material is in a metastable state; and
a strain-compensating atomic species doped substitutionally into the compound semiconductor.

25. The electronic device of claim 24 wherein the compound semiconductor is comprised substantially of silicon germanium.

26. The electronic device of claim 25 wherein the first semiconducting material of the compound semiconductor is germanium.

27. The electronic device of claim 24 wherein the strain-compensating species is carbon.

28. A method for fabricating a heterojunction bipolar transistor, the method comprising:
providing a substrate, the substrate having a first surface;
forming a silicon-germanium film over the first surface of the substrate, the silicon germanium film selected to be in a metastable state; and
doping the compound semiconductor film with a strain-compensating atomic species, the strain-compensating atomic species comprising carbon.

29. The method of claim 28 further comprising tailoring the first semiconducting material to have a trapezoidal concentration profile shape.

30. The method of claim 28 further comprising tailoring the first semiconducting material to have a triangular concentration profile shape.

31. The method of claim 28 further comprising tailoring the first semiconducting material to have a box concentration profile shape.

32. The method of claim 28 further comprising tailoring the first semiconducting material to have a curved concentration profile.
